(19) United States
(12) Patent Application Publication
(10) Pub. No.: US 2023/0361113 A1
(43) Pub. Date: Nov. 9, 2023

(54) WIDE-BANDGAP CHIP HAVING REFERENCE DEVICE

(71) Applicant: SKYWORKS SOLUTIONS, INC., Irvine, CA (US)

(72) Inventors: Lui Ray LAM, Lexington, MA (US); Guillaume Alexandre BLIN, Carlisle, MA (US); Raymond WAUGH, Tewksbury, MA (US); Eric J. MARSAN, Lowell, MA (US); Min CHU, Lake Forest, CA (US)

(21) Appl. No.: 18/120,287

(22) Filed: Mar. 10, 2023

Related U.S. Application Data
(60) Provisional application No. 63/318,773, filed on Mar. 10, 2022.

(51) Int. Cl. H01L 27/088; H01L 27/07; H01L 29/20

(52) U.S. Cl. CPC H01L 27/088; H01L 27/0705; H01L 29/2003

(57) ABSTRACT

In some embodiments, a semiconductor chip can include a substrate, an active wide-bandgap device implemented on the substrate, and a reference wide-bandgap device implemented on the substrate. The reference wide-bandgap device can be configured to provide a response to a condition that also affects the active wide-bandgap device. Such a semiconductor chip can be included in an architecture that allows operation of the active wide-bandgap device based on the response provided by the reference wide-bandgap device.

### CROSS-REFERENCE TO RELATED APPLICATION(S)

This application claims priority to U.S. Provisional Application No. 63/318,773 filed Mar. 10, 2022, entitled WIDE-BANDGAP CHIP HAVING REFERENCE DEVICE, the disclosure of which is hereby expressly incorporated by reference herein in its entirety.

### BACKGROUND

### Field

The present disclosure relates to semiconductor chips having wide-bandgap.

### Description of the Related Art

Wide-bandgap semiconductor materials have larger band gaps, typically in a range above 2 eV. Such a property allows a wide-bandgap semiconductor chip to operate in conditions that would not be suitable for semiconductor materials such as silicon. Such conditions can include, for example, higher voltage and temperature.

### SUMMARY

In accordance with a number of implementations, the present disclosure relates to a semiconductor chip that includes a substrate, an active wide-bandgap device implemented on the substrate, and a reference wide-bandgap device implemented on the substrate. The reference wide-bandgap device is configured to provide a response to a condition that also affects the active wide-bandgap device.

In some embodiments, each of the active wide-bandgap device and the reference wide-bandgap device can be implemented as a respective wide-bandgap transistor. In some embodiments, the active wide-bandgap transistor can be configured to receive and process a radio-frequency signal, and the reference wide-bandgap transistor can be configured to not receive a radio-frequency signal.

In some embodiments, each of the active wide-bandgap transistor and the reference wide-bandgap transistor can be configured to receive a respective radio-frequency signal. The active wide-bandgap transistor and the reference wide-bandgap transistor can be arranged in a mirror device configuration with a resistance provided between gates of the active wide-bandgap transistor and the reference wide-bandgap transistor. The radio-frequency signal received by the reference wide-bandgap transistor can be representative of the radio-frequency signal received by the active wide-bandgap transistor.

In some embodiments, each of the active wide-bandgap transistor and the reference wide-bandgap transistor can be configured to receive a respective bias signal during operation. The bias signal provided to the reference wide-bandgap transistor can be adjusted in response to the condition during the operation. The adjusted bias signal can include an adjustment resulting from a feedback during the operation. The adjusted bias signal for the reference wide-bandgap transistor can be utilized as a reference for generation of the bias signal for the active wide-bandgap transistor.

In some embodiments, each of the active wide-bandgap transistor and the reference wide-bandgap transistor can be configured as a field-effect transistor having a gate, a drain and a source. The field-effect transistor can have a finger configuration, such that each gate having a width is implemented between the respective drain and source. The active wide-bandgap transistor can have N fingers, and the reference wide-bandgap transistor can have less than N fingers. For example, the active wide-bandgap transistor can have multiple fingers, and the reference wide-bandgap transistor can have one finger.

In some embodiments, the reference wide-bandgap transistor can have at least one scaled-down dimension relative to the active wide-bandgap transistor. The scaled-down dimension can include the width of the gate.

In some embodiments, the active wide-bandgap transistor and the reference wide-bandgap transistor can be physically separate from each other. In some embodiments, the active wide-bandgap transistor and the reference wide-bandgap transistor can share a common portion. Such a common portion can include, for example, a common source region.

In some embodiments, the semiconductor chip can further include one or more additional active wide-bandgap devices implemented on the substrate, such that the response provided by the reference wide-bandgap device is utilized for each of the active wide-bandgap devices. For example, the reference wide-bandgap device can be implemented between two or more of the active wide-bandgap devices.

In some implementations, the present disclosure relates to a module that includes a packaging substrate and a first die mounted on the packaging substrate. The first die includes a semiconductor substrate, an active wide-bandgap transistor implemented on the semiconductor substrate, and a reference wide-bandgap transistor implemented on the semiconductor substrate, with the reference wide-bandgap transistor being configured to provide a response to a condition that also affects the active wide-bandgap transistor. The module further includes a second die mounted on the packaging substrate and in communication with the first die. The second die includes a biasing circuit configured to provide a bias signal to each of the active wide-bandgap transistor and the reference wide-bandgap transistor.

In some embodiments, the biasing circuit can include a first bias supply circuit configured to provide the bias signal to the active wide-bandgap transistor, and a second bias supply circuit configured to provide the bias signal to the reference wide-bandgap transistor.

In some embodiments, the biasing circuit can further include a current source configured to provide a reference current as an input to the second bias supply circuit, and the second bias supply circuit can be configured provide an output to an input of the reference wide-bandgap transistor.

In some embodiments, the biasing circuit can further include a feedback circuit having a feedback path between an output of the reference wide-bandgap transistor and the input of the second bias supply circuit so as to allow adjustment of the output of the second bias supply circuit in response to a change in the operation of the reference wide-bandgap transistor due to the condition. The biasing circuit can further include a connection between the output of the second bias supply circuit and an input of the first bias supply circuit, such that the adjusted output of the second bias supply circuit is utilized as a reference for the input of the first bias supply circuit.

In some embodiments, the biasing circuit can be configured to provide an offset for an input of the first bias supply circuit.

In some implementations, the present disclosure relates to a radio-frequency device that includes a radio-frequency circuit configured to process a signal, and an amplifier configured to amplify the signal from the radio-frequency circuit or to provide the signal to the radio-frequency circuit. The amplifier has an amplifier architecture that includes a first die with an active wide-bandgap transistor and a reference wide-bandgap transistor, with the reference wide-bandgap transistor configured to provide a response to a condition that also affects the active wide-bandgap transistor. The amplifier architecture further includes a second die in communication with the first die, with the second die including a biasing circuit configured to provide a bias signal to each of the active wide-bandgap transistor and the reference wide-bandgap transistor. The radio-frequency device further includes an antenna in communication with the amplifier and configured to support a transmit operation or a receive operation.

In some embodiments, the amplifier can be a power amplifier configured to amplify the signal from the radio-frequency circuit for transmission through the antenna.

In some embodiments, the biasing circuit can include a first bias supply circuit configured to provide the bias signal to the active wide-bandgap transistor, and a second bias supply circuit can be configured to provide the bias signal to the reference wide-bandgap transistor.

In some embodiments, the biasing circuit can further include a current source configured to provide a reference current as an input to the second bias supply circuit, and the second bias supply circuit can be configured provide an output to an input of the reference wide-bandgap transistor.

In some embodiments, the biasing circuit can further include a feedback circuit having a feedback path between an output of the reference wide-bandgap transistor and the input of the second bias supply circuit so as to allow adjustment of the output of the second bias supply circuit in response to a change in the operation of the reference wide-bandgap transistor due to the condition.

In some embodiments, the biasing circuit can further include a connection between the output of the second bias supply circuit and an input of the first bias supply circuit, such that the adjusted output of the second bias supply circuit is utilized as a reference for the input of the first bias supply circuit.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 depicts a conventional control architecture for operation of a transistor that is implemented on a wide-bandgap (WBG) chip.

FIG. 2 shows that in some embodiments, a wide-bandgap chip having one or more features as described herein can include an active device and a reference device.

FIG. 3 shows an example of a wide-bandgap chip that includes an assembly of an active device and a reference device, with the active device including an active portion and the reference device including a reference portion, where the active portion and the reference portion can be implemented to be physically separate from each other.

FIG. 4 shows another example of a wide-bandgap chip that includes an assembly of an active device and a reference device, with the active device including an active portion and the reference device including a reference portion, where the active portion and the reference portion can be implemented to be in respective regions having neighboring boundaries or overlapping portions.

FIG. 5 shows an example architecture that can be implemented utilizing the wide-bandgap chip of FIG. 2.

FIG. 6 shows a wide-bandgap chip that can be a more specific example of the wide-bandgap chip of FIG. 3.

FIG. 7 shows an architecture that can be implemented utilizing the wide-bandgap chip of FIG. 6.

FIG. 8 shows a wide-bandgap chip that can be a more specific example of the wide-bandgap chip of FIG. 4.

FIG. 9 show a wide-bandgap chip having an active device and a reference device, with a source of the active device being connected to a source of the reference device to have a common source voltage when in operation.

FIG. 10 shows a wide-bandgap chip having a chip substrate configured to support a wide-bandgap active device and a wide-bandgap reference device.

FIG. 11 shows that in some embodiments, the active and reference devices of FIG. 10 can be provided with bias signals similar to the example of FIG. 9.

FIG. 12 shows that in come embodiments, a biasing architecture can include an additional control offset being provided to a bias signal for an active device, with sources of the active device and the reference device being coupled similar to the examples of FIGS. 9 and 11.

FIG. 13 shows that in come embodiments, a biasing architecture can include an additional control offset being provided to a bias signal for an active device, with sources of the active device and the reference device not being coupled similar to the example of FIG. 7.

FIG. 14 shows that in some embodiments, one or more features of the present disclosure can be implemented on a semiconductor die.

FIG. 15 shows that in some embodiments, one or more features of the present disclosure can be implemented on a module.

FIG. 16 shows that in some embodiments, one or more features of the present disclosure can be implemented in a radio-frequency device.

### DETAILED DESCRIPTION OF SOME EMBODIMENTS

The headings provided herein, if any, are for convenience only and do not necessarily affect the scope or meaning of the claimed invention.

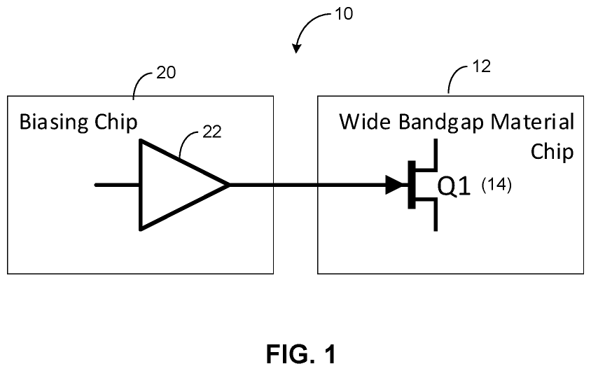

FIG. 1 depicts a conventional control architecture 10 for operation of a transistor 14 (Q1) that is implemented on a wide-bandgap (WBG) chip 12. In such a control architecture, a bias circuit 22 implemented on a separate chip (e.g., a biasing chip 20) is shown to provide a bias signal to a gate of the transistor Q1 for operation of the transistor Q1. Such a biasing architecture is an open loop architecture; thus, the bias circuit 22 does not receive feedback related to one or more conditions associated with the transistor Q1. Such conditions can include, for example, process variation, voltage variation, temperature variation, transient variation and/or aging effect that impact the operation of the transistor Q1.

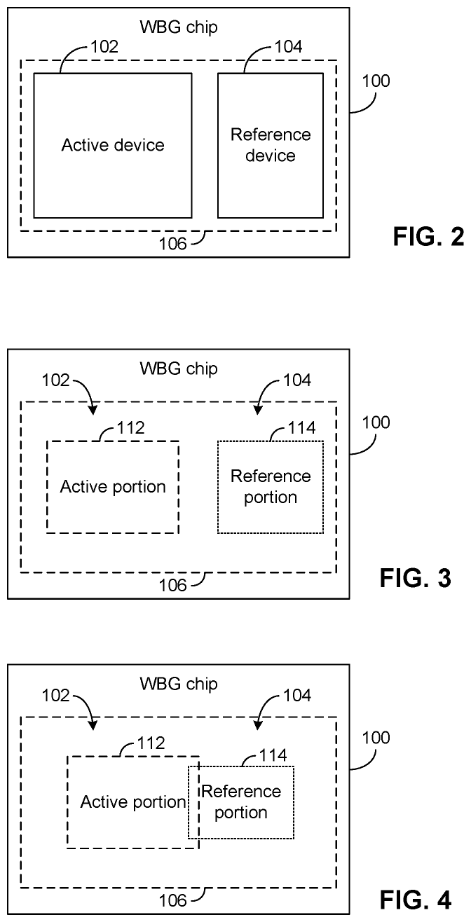

FIG. 2 shows that in some embodiments, a wide-bandgap (WBG) chip 100 having one or more features as described herein can include an active device 102 and a reference device 104. Both of such devices implemented on the wide-bandgap chip 100 is collectively indicated as 106.

In some embodiments, each of the active device 102 and the reference device 104 of FIG. 2 can be a transistor. In such an example, the active transistor can be operated to provide its functionality (e.g., processing of a radio-frequency (RF) signal by being provided with a bias signal), and the reference transistor can also be operated but without providing its functionality (e.g., being provided with a bias signal, but no RF signal).

In some embodiments, the foregoing active transistor can be implemented as an active amplifier transistor configured to process an RF signal by being provided with a bias signal, and the reference transistor can be implemented as an amplifier-like transistor provided with a bias signal but no RF signal. It will be understood that although the active and reference devices 102, 104 are described in the context of amplifier transistors, the active and reference devices 102, 104 can also be implemented as other types of devices including other types of transistors.

FIG. 3 shows an example of a wide-bandgap chip 100 that includes an assembly 106 of an active device 102 and a reference device 104 as described in reference to FIG. 2, with the active device 102 including an active portion 112, and the reference device 104 including a reference portion 114. In some embodiments, the active portion 112 and the reference portion 114 can be implemented to be physically separate from each other.

FIG. 4 shows another example of a wide-bandgap chip 100 that includes an assembly 106 of an active device 102 and a reference device 104 as described in reference to FIG. 2, with the active device 102 including an active portion 112, and the reference device 104 including a reference portion 114. In some embodiments, the active portion 112 and the reference portion 114 can be implemented to be in respective regions having neighboring boundaries or overlapping portions.

Although various examples are described herein in the context of a wide-bandgap (WBG) chip with one active portion of an active device and one reference portion of a reference device, it will be understood that a wide-bandgap chip as described herein can include one or more active portions and one or more reference portions. For example, a wide-bandgap chip can include a reference device implemented between two active devices (with or without overlapping region(s)), and such active devices can be operated based on operation of the reference device. In another example, a reference device can be implemented at a location of a wide-bandgap chip where operating condition variation may be expected, and such a reference device can be utilized to operate one or more active devices about the reference device.

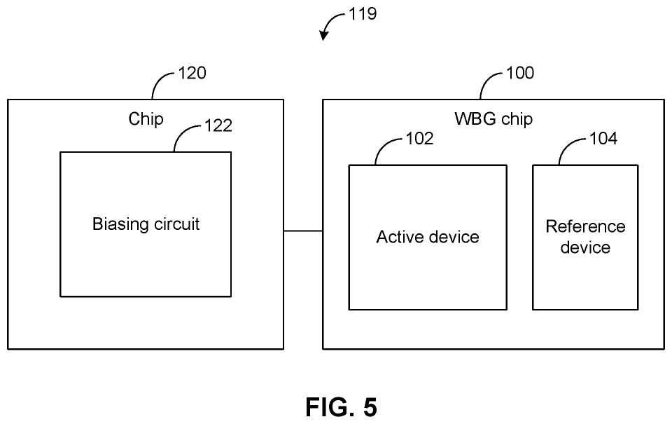

FIG. 5 shows an architecture 119 that can be implemented utilizing the wide-bandgap chip of FIG. 2. In FIG. 5, the architecture 119 is shown to include a wide-bandgap chip 100 having an active device 102 and a reference device 104, and a separate chip 120 having a biasing circuit 122. The biasing circuit 122 can be configured to be in communication with the active device 102 and the reference device 104 to operate the active device 102 in an improved manner. Examples of wide-bandgap chips and biasing circuits that can be utilized for the architecture 119 are described herein in greater detail.

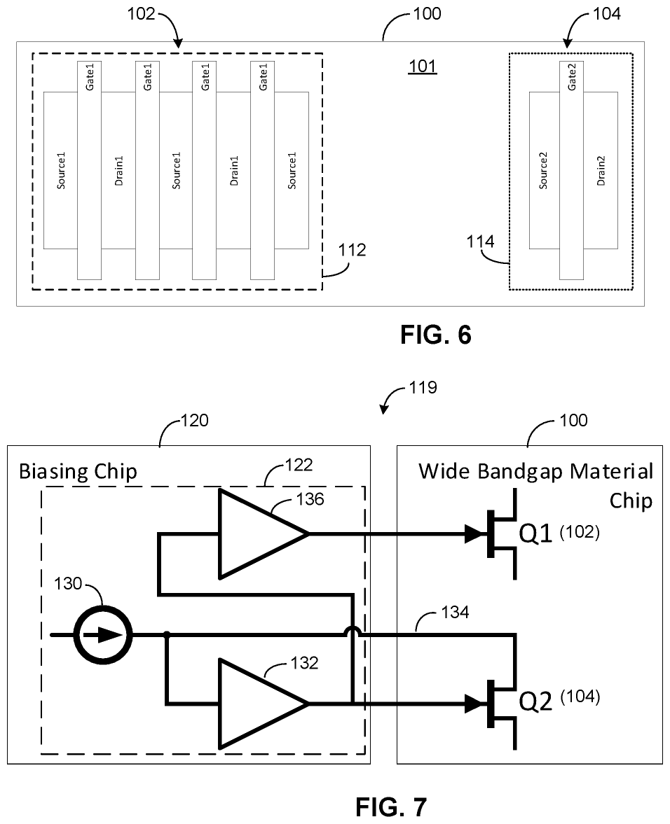

For example, FIG. 6 shows a wide-bandgap chip 100 that can be a more specific example of the wide-bandgap chip 100 of FIG. 3, and FIG. 7 shows an architecture 119 that can be implemented utilizing the wide-bandgap chip 100 of FIG. 6. More particularly, the wide-bandgap chip 100 of FIG. 6 can include a chip substrate 101 configured to support a wide-bandgap active device 102 and a wide-bandgap reference device 104. The example active device 102 is shown to be implemented as a multi-finger transistor having multiple gates (Gate1) interleaved between alternating source (Source1) and drain (Drain1) regions. The example reference device 104 is shown to be implemented as a single-finger transistor having a gate (Gate2) between source (Source2) and drain (Drain2) regions.

In the example of FIG. 6, the active and reference devices 102, 104 are separated on the substrate 101, such that respective active and reference portions 112, 114 do not engage or overlap each other.

In the example of FIG. 6, the width dimensions of the gate and source/drain of the active device 102 are depicted as being approximately the same as the width dimensions of the gate and source/drain of the reference device 104. It will be understood that such dimensions among the active and reference devices may or may not be the same.

FIG. 7 shows an architecture 119 that can be implemented utilizing the wide-bandgap chip 100 of FIG. 6. In FIG. 7, the active and reference devices 102, 104 of FIG. 6 are depicted as transistors Q1, Q2 (102, 104), respectively, with Q1 and Q2 not having a direct coupling therebetween. The active device Q1 is shown to be provided with a bias signal from a first bias supply circuit 136, and the reference device Q2 is shown to be provided with a bias signal from a second bias supply circuit 132. In the example of FIG. 7, the first and second bias supply circuits 136, 132 are collectively indicated as a bias circuit 122.

Among others, FIG. 7 shows that in some embodiments, a bias signal being provided to the active device Q1 (e.g., to its gate) can be based on a feedback that depends on one or more conditions associated with the reference device Q2. As an example, the second bias supply circuit 132 is shown to receive as an input a current from a current source 130, and output a bias signal that is provided to an input of the reference device Q2 (e.g., at a gate of Q2). A feedback is shown to be provided between an output (e.g., at a drain of Q2) and the input of the second bias supply circuit 132 through a feedback path 134. Thus, operation of the second bias supply circuit 132 can be adjusted based on the output of the reference device Q2.

Referring to FIG. 7, the output of the second bias supply circuit 132 is shown to provide an input for the first bias supply circuit 136, and an output of the first bias supply circuit 136 is shown to be provided to an input of the active device Q1 (e.g., at a gate of Q1). Accordingly, the bias signal provided to Q1 reflects the feedback-adjusted output of the second bias supply circuit 132.

In some embodiments, and referring to FIG. 7, the placement and utilization of the reference device Q2 on the wide-bandgap chip 100 can allow adjustment in operation of the active device Q1 based on some or all of variations (e.g., process variation, voltage variation, temperature variation, transient variation and aging effect) that affect the wide-bandgap chip to first order.

In the example of FIG. 7, source of Q1 and source of Q2 may or may not have the same voltage when in operation. If the latter, the source of Q1 can be uncoupled from the source of Q2. If the former, the source of Q1 can be coupled to the source of Q2.

FIG. 9 show a wide-bandgap chip 100 having an active device Q1 and a reference device Q2, with a source of Q1 being connected to a source of Q2 to have a common source voltage when in operation. It is noted that such a coupling between Q1 and Q2 can provide better tracking of one or more conditions.

As shown in FIG. 9, the active and reference devices Q1, Q2 can be provided with respective bias signals similar to the example of FIG. 7. Such biasing of Q1 and Q2 can include an output of the second bias supply circuit 132 (based on a feedback from Q2) being provided to an input for the first bias supply circuit 136, such that and an output of the first bias supply circuit 136 being provided to an input of the active device Q1 (e.g., at a gate of Q1) reflects the feedback-adjusted output of the second bias supply circuit 132. Accordingly, the placement and utilization of the reference device Q2 on the wide-bandgap chip 100 can allow adjustment in operation of the active device Q1 based on some or all of variations (e.g., process variation, voltage variation, temperature variation, transient variation and aging effect) that affect the wide-bandgap chip.

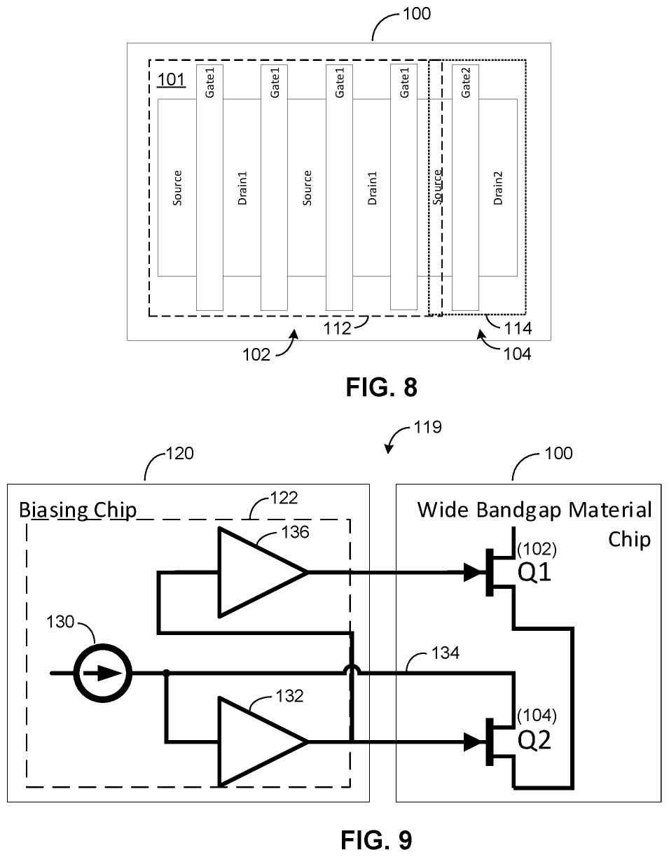

FIG. 8 shows an example of how the wide-bandgap chip 100 of FIG. 9 can be implemented. Also, FIG. 8 shows a wide-bandgap chip 100 that can be a more specific example of the wide-bandgap chip 100 of FIG. 4, where the active portion and the reference portion overlap.

In the example of FIG. 8, the wide-bandgap chip 100 can include a chip substrate 101 configured to support a wide-bandgap active device 102 and a wide-bandgap reference device 104. The example active device 102 is shown to be implemented as a multi-finger transistor having multiple gates (Gate1) interleaved between alternating source (Source) and drain (Drain1) regions. The example reference device 104 is shown to be implemented as a single-finger transistor having a gate (Gate2) between a common source (Source) region and a drain (Drain2) region. In the example of FIG. 8, the common source (Source) provides the connection between the active device 102 (Q1 in FIG. 9) and the reference device 104 (Q2 in FIG. 9).

In the example of FIG. 8, the active and reference devices 102, 104 are coupled on the substrate 101, such that respective active and reference portions 112, 114 engage or overlap each other.

In the example of FIG. 8, the width dimensions of the gate and source/drain of the active device 102 are depicted as being approximately the same as the width dimensions of the gate and source/drain of the reference device 104. It will be understood that such dimensions among the active and reference devices may or may not be the same.

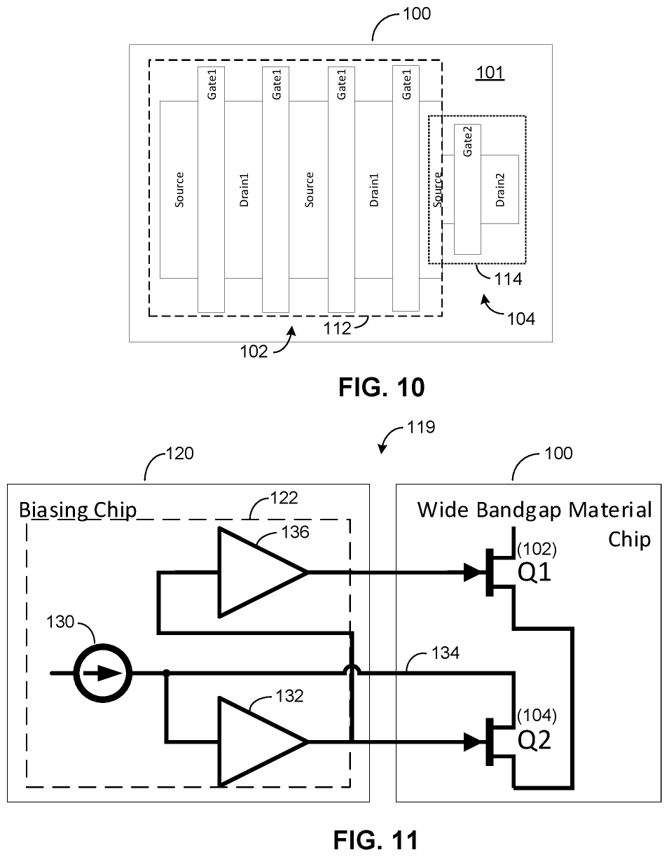

For example, FIG. 10 shows a wide-bandgap chip 100 having a chip substrate 101 configured to support a wide-bandgap active device 102 and a wide-bandgap reference device 104. The example active device 102 is shown to be implemented as a multi-finger transistor having multiple gates (Gate1) interleaved between alternating source (Source) and drain (Drain1) regions. The example reference device 104 is shown to be implemented as a single-finger transistor having a gate (Gate2) between a common source (Source) region and a drain (Drain2) region.

In the example of FIG. 10, the active and reference devices 102, 104 are coupled on the substrate 101, such that respective active and reference portions 112, 114 engage or overlap each other.

In the example of FIG. 10, the width dimension of each of the gate and drain of the reference device 104 is less than the width dimension of each of the gate and drain of the active device 102. The common source (Source) is shown to include a larger-width portion on the active device side, and a smaller-width portion on the reference device side.

FIG. 11 shows that in some embodiments, the active and reference devices 102, 104 of FIG. 10 can be provided with bias signals similar to the example described herein in reference to FIG. 9.

It is noted that in the example of FIG. 10, the scaled-down dimensions of the reference device 104 can provide improved flexibility by, for example, having the reference device 104 consuming less reference current during operation.

In the example of FIG. 10, the reference device 104 is depicted as being scaled-down compared to the active device 102. It will be understood that in some embodiments, a wide-bandgap chip having one or more features as described herein can include a reference device that is scaled-up compared to a respective active device.

It is also noted that in the examples of FIGS. 6, 8 and 10, the reference devices 104 are depicted as having a smaller finger count (e.g., 1) than the corresponding active devices 102 (e.g., 4). It will be understood that in some embodiments, a wide-bandgap chip having one or more features as described herein can include a reference device that having a finger count that is equal to or greater than that of an active device.

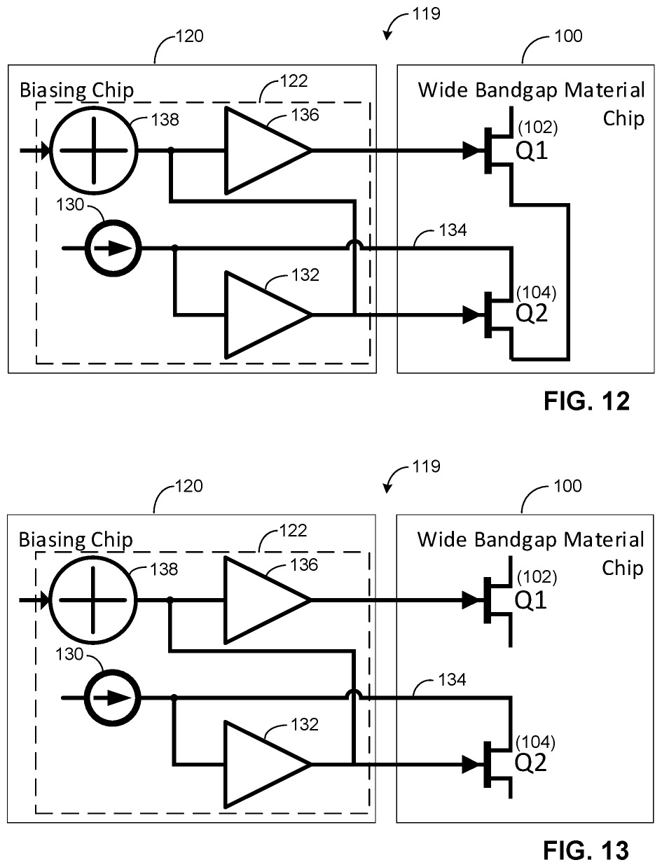

FIGS. 12 and 13 show that in some embodiments, a biasing architecture 119 can include an additional control offset being provided to a bias signal for an active device Q1. In some embodiments, such an additional offset can be provided through an offset signal provided to an input of a bias supply circuit 136 through a summing circuit 138, to provide performance enhancement.

In the example of FIG. 12, the sources of the active device Q1 and the reference device Q2 are coupled, similar to the examples of FIGS. 9 and 11. In the example of FIG. 13, the sources of the active device Q1 and the reference device Q2 are not coupled, similar to the example of FIG. 7.

In some embodiments, a wide-bandgap chip having one or more features as described herein can include wide-bandgap semiconductor material having a bandgap that is greater than 2 eV, including, for example, gallium nitride (GaN). In some embodiments, such a wide-bandgap chip can be suitable for implementation of transistors thereon, including, for example, amplifying transistors.

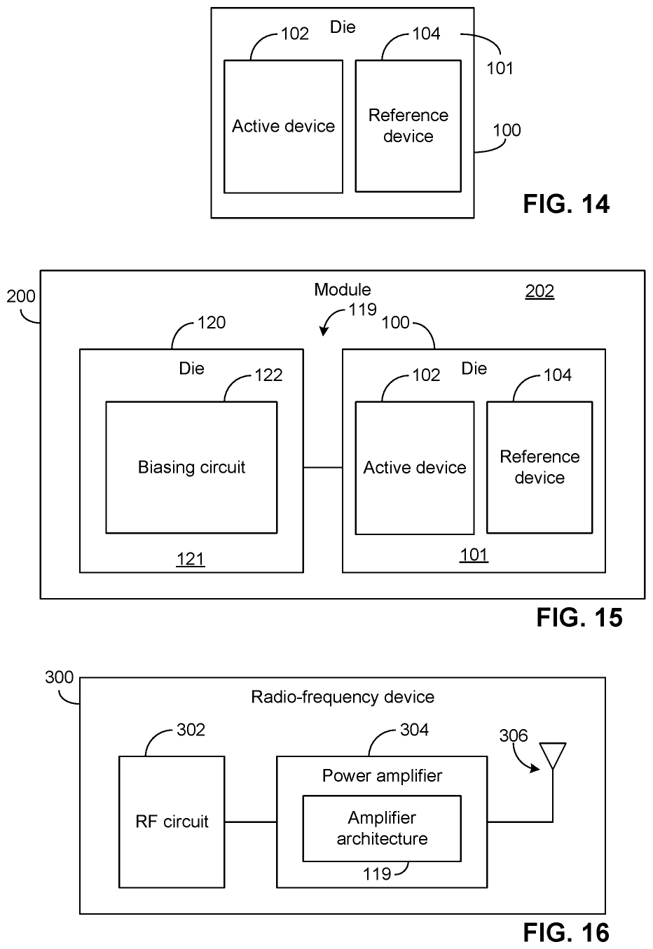

FIG. 14 shows that in some embodiments, one or more features of the present disclosure can be implemented on a semiconductor die 100 having a substrate 101, with an active device 102 and a reference device 104 implemented thereon. For the purpose of description, such a die can be referred to as a chip; thus, the die 100 of FIG. 14 can be implemented as a wide-bandgap die having one or more features as described herein.

FIG. 15 shows that in some embodiments, one or more features of the present disclosure can be implemented on a module 200. Such a module can include a packaging substrate 202, and a wide-bandgap die 100 such as the wide-bandgap die 100 of FIG. 14 can be mounted on the packaging substrate 202.

In some embodiments, the module 200 can further include a separate die 120 having a substrate 121, and a biasing circuit 122 implemented thereon. In some embodiments, the die 120 with the biasing circuit 122 and the wide-bandgap die 100 can be electrically connected directly, through the packaging substrate 202, or some combination thereof.

FIG. 16 shows that in some embodiments, one or more features of the present disclosure can be implemented in a radio-frequency (RF) device 300. Such a device can include an RF circuit 302 (e.g., a transmit circuit or a transceiver circuit) configured to generate a signal to be transmitted. The RF device 300 can further include a power amplifier 304 configured to amplify the signal from the RF circuit 302, and such an amplified signal can be provided to an antenna for transmission.

In some embodiments, the power amplifier 304 can include an amplifier architecture 119 having one or more features as described herein. Such an amplifier architecture can be or include any of the example architectures of FIGS. 5, 7, 9, 11-13 and 15.

In some embodiments, the radio-frequency device 300 of FIG. 16 can be implemented as a wireless device such as a mobile device having a battery. In some embodiments, the radio-frequency device 300 of FIG. 16 can be implemented to operate at a fixed location with power being provided from an external source.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A semiconductor chip comprising:
a substrate;
an active wide-bandgap device implemented on the substrate; and
a reference wide-bandgap device implemented on the substrate, the reference wide-bandgap device configured to provide a response to a condition that also affects the active wide-bandgap device.

2. The semiconductor chip of claim 1 wherein each of the active wide-bandgap device and the reference wide-bandgap device is implemented as a respective wide-bandgap transistor.

3. The semiconductor chip of claim 2 wherein the active wide-bandgap transistor is configured to receive and process a radio-frequency signal, and the reference wide-bandgap transistor is configured to not receive a radio-frequency signal.

4. The semiconductor chip of claim 2 wherein each of the active wide-bandgap transistor and the reference wide-bandgap transistor is configured to receive a respective radio-frequency signal.

5. The semiconductor chip of claim 4 wherein the active wide-bandgap transistor and the reference wide-bandgap transistor are arranged in a mirror device configuration with a resistance provided between gates of the active wide-bandgap transistor and the reference wide-bandgap transistor.

6. The semiconductor chip of claim 4 wherein the radio-frequency signal received by the reference wide-bandgap transistor is representative of the radio-frequency signal received by the active wide-bandgap transistor.

7. The semiconductor chip of claim 2 wherein each of the active wide-bandgap transistor and the reference wide-bandgap transistor is configured to receive a respective bias signal during operation.

8. The semiconductor chip of claim 7 wherein the bias signal provided to the reference wide-bandgap transistor is adjusted in response to the condition during the operation.

9. The semiconductor chip of claim 8 wherein the adjusted bias signal includes an adjustment resulting from a feedback during the operation.

10. The semiconductor chip of claim 8 wherein the adjusted bias signal for the reference wide-bandgap transistor is utilized as a reference for generation of the bias signal for the active wide-bandgap transistor.

11. The semiconductor chip of claim 2 wherein each of the active wide-bandgap transistor and the reference wide-bandgap transistor is configured as a field-effect transistor having a gate, a drain and a source.

12. The semiconductor chip of claim 11 wherein the field-effect transistor has a finger configuration, such that each gate having a width is implemented between the respective drain and source.

13. The semiconductor chip of claim 12 wherein the active wide-bandgap transistor has N fingers, and the reference wide-bandgap transistor has less than N fingers.

14. The semiconductor chip of claim 13 wherein the active wide-bandgap transistor has multiple fingers, and the reference wide-bandgap transistor has one finger.

15. The semiconductor chip of claim 12 wherein the reference wide-bandgap transistor has at least one scaled-down dimension relative to the active wide-bandgap transistor.

16. The semiconductor chip of claim 15 wherein the scaled-down dimension includes the width of the gate.

17. The semiconductor chip of claim 2 wherein the active wide-bandgap transistor and the reference wide-bandgap transistor are physically separate from each other.

18. The semiconductor chip of claim 2 wherein the active wide-bandgap transistor and the reference wide-bandgap transistor share a common portion.

19. The semiconductor chip of claim 18 wherein the common portion includes a common source region.

20. The semiconductor chip of claim 1 further comprising one or more additional active wide-bandgap devices implemented on the substrate, such that the response provided by the reference wide-bandgap device is utilized for each of the active wide-bandgap devices.

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)
